(19) United States
(12) Patent Application Publication
(10) Pub. No.: US 2026/0293159 A1
(43) Pub. Date: Sep. 24, 2026

(54) HIGH-DENSITY INTERCONNECT FOR SEMICONDUCTOR DIE AND MEMORY INTEGRATION

(71) Applicant: QUALCOMM Incorporated, San Diego, CA (US)

(72) Inventors: Aniket PATIL, San Diego, CA (US); Li-Sheng WENG, San Diego, CA (US); Hong Bok WE, San Diego, CA (US)

(21) Appl. No.: 19/082,574

(22) Filed: Mar. 18, 2025

(51) Int. Cl. H01L 23/00; H01L 25/18; H10B 80/00; H10D 80/30

(52) U.S. Cl. CPC H10B 80/00; H10W 90/00; H10D 80/30; H10W 70/09; H10W 70/60; H10W 70/6528; H10W 90/10

(57) ABSTRACT

Disclosed are techniques for providing high-density interconnect for semiconductor die and memory integration. In an aspect, an apparatus comprises a multi-layer substrate and one or more metallization layers disposed on a top surface of the substrate. Both a semiconductor die and a memory device are mounted to the metallization layers with contact pads facing the metallization layers. A first subset of die contacts are on a first side of the die adjacent to the memory device and are electrically connected to some of the memory device contacts by conductive traces in the metallization layers routed directly from the first side of the die. A second subset of die contacts are disposed on a second side of the die opposite the first side and are electrically connected to others of the memory device contacts by conductive traces in the metallization layers routed beneath the die.

### BACKGROUND OF THE DISCLOSURE

### 1. Field of the Disclosure

Aspects of the disclosure relate generally to semiconductor devices and more specifically to high-density interconnects between semiconductor dies and memory devices.

### 2. Description of the Related Art

The combination of a system-on-chip (SOC) device (e.g., a single packaged device having a processor core and other functions needed for a complete system, such as an interrupt controller, direct memory access (DMA) controller, serial bus or input/output (I/O) controllers, memory controllers, and other peripherals) and DRAM memory in a single packaged assembly can provide a capable platform for many processing tasks. It is desirable to provide such a combination of SOC or other semiconductor device and DRAM or other memory device in as compact a footprint as possible but without creating problems related to thermal management and without negatively affecting signal integrity and operational speed.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an apparatus includes a multi-layer substrate having a first line pitch; one or more metallization layers disposed on a first surface of the substrate and having a second line pitch that is smaller than the first line pitch; a semiconductor die mounted to a first surface of the one or more metallization layers opposite from the substrate such that a plurality of semiconductor die contacts are electrically coupled to the one or more metallization layers; and a memory device mounted to the first surface of the one or more metallization layers such that a plurality of memory device contacts are electrically coupled to the one or more metallization layers, wherein a first subset of the semiconductor die contacts are disposed on a first side of the die adjacent the memory device are electrically connected to a first subset of the memory device contacts by a first plurality of conductive traces in the one or more metallization layers routed directly from the first side to the die, and wherein a second subset of the semiconductor die contacts are disposed on a second side of the die opposite the first side and are electrically connected to a second subset of the memory device contacts by a second plurality of conductive traces in the one or more metallization layers routed beneath the semiconductor die.

In an aspect, a method for fabricating an apparatus includes providing a multi-layer substrate having a first line pitch; forming one or more metallization layers on a first surface of the substrate and having a second line pitch that is smaller than the first line pitch; mounting a semiconductor die to a first surface of the one or more metallization layers opposite from the substrate such that a plurality of semiconductor die contacts are electrically coupled to the one or more metallization layers; and mounting a memory device to the first surface of the one or more metallization layers such that a plurality of memory device contacts are electrically coupled to the one or more metallization layers, wherein a first subset of the semiconductor die contacts are disposed on a first side of the die adjacent the memory device are electrically connected to a first subset of the memory device contacts by a first plurality of conductive traces in the one or more metallization layers routed directly from the first side to the die, and wherein a second subset of the semiconductor die contacts are disposed on a second side of the die opposite the first side and are electrically connected to a second subset of the memory device contacts by a second plurality of conductive traces in the one or more metallization layers routed beneath the semiconductor die.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 is a plan view of a conventional side-by-side (S×S) package-on-package (POP) device in which dynamic random access memories (DRAMs) are located on either side of a system-on-chip (SOC) device.

FIGS. 2A-C are various views of a conventional S×S POP device in which the DRAMs are grouped together on one side of the SOC.

FIG. 3A and FIG. 3B are a plan view and a cross-sectional view, respectively, of a POP device according to aspects of the disclosure.

FIG. 3C is a simplified plan view of a POP device according to aspects of the disclosure.

FIG. 4 illustrates an aspect in which a redistribution layer (RDL) other high-density, fine-pitched structures may be used as a pin layout converter, according to aspects of the disclosure.

FIG. 5A through FIG. 5J illustrate portions of a process for fabricating a high-density interconnect for semiconductor die and memory integration, according to aspects of the disclosure.

FIG. 6 is a flowchart of an example method for fabricating a semiconductor apparatus having a high-density interconnect for semiconductor die and memory integration, according to aspects of the disclosure.

FIG. 7 illustrates a mobile device, according to aspects of the disclosure.

FIG. 8 illustrates various electronic devices that may be integrated with any device or apparatus disclosed herein.

### DETAILED DESCRIPTION

Disclosed are techniques for providing high-density interconnect for semiconductor die and memory integration. In an aspect, an apparatus comprises a multi-layer substrate and one or more metallization layers disposed on a top surface of the substrate. Both a semiconductor die and a memory device are mounted to the one or more metallization layers with contact pads facing the one or more metallization layers. A first subset of die contacts are on a first side of the die adjacent to the memory device and are electrically connected to some of the memory device contacts by conductive traces in the one or more metallization layers routed directly from the first side of the die. A second subset of die contacts are disposed on a second side of the die opposite the first side and are electrically connected to others of the memory device contacts by conductive traces in the one or more metallization layers routed beneath the die

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure. Directional terms such as upper, lower, above, and below are used herein for ease of description and often refer to illustrations in the application figures. Such terms are not necessarily descriptive of a physical direction or disposition or positioning of a device.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

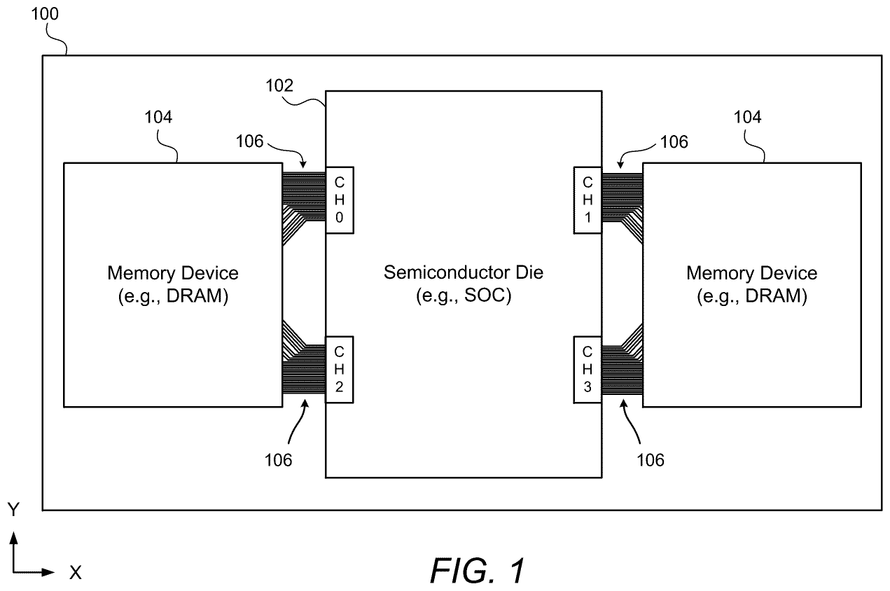

FIG. 1 is a plan view of a conventional side-by-side (S×S) package-on-package (POP) device having a substrate 100 upon which a semiconductor die 102 (e.g., a system-on-chip (SOC) device) and two memory devices 104 (e.g., DRAMs) are mounted. The semiconductor die 102 and memory devices 104 are mounted with electrical contacts facing the top surface of the substrate 100, which is referred to as a flip-chip configuration. The semiconductor die 102 has four different double data rate (DDR) DRAM physical layer interfaces (PHYs), two each on opposite sides of the semiconductor die 102. In the example shown in FIG. 1, the PHYs are labeled channel 0 (CH0), channel 1 (CH1), channel 2 (CH2), and channel 3 (CH3). Four sets of electrical traces 106 on the substrate connect the PHYs to the memory devices.

The S×S package has advantages over “stacked” configurations in which the semiconductor die 102 and memory devices 104 are stacked vertically, one advantage being thermal management of the semiconductor die 102 independent from the memory devices 104. That is, the heatsink for the semiconductor die 102 can be a different size, shape, or capacity than the heatsinks for each of the memory devices 104. However, having the memory devices 104 on two sides of the semiconductor die 102 means that three heatsink structures are required.

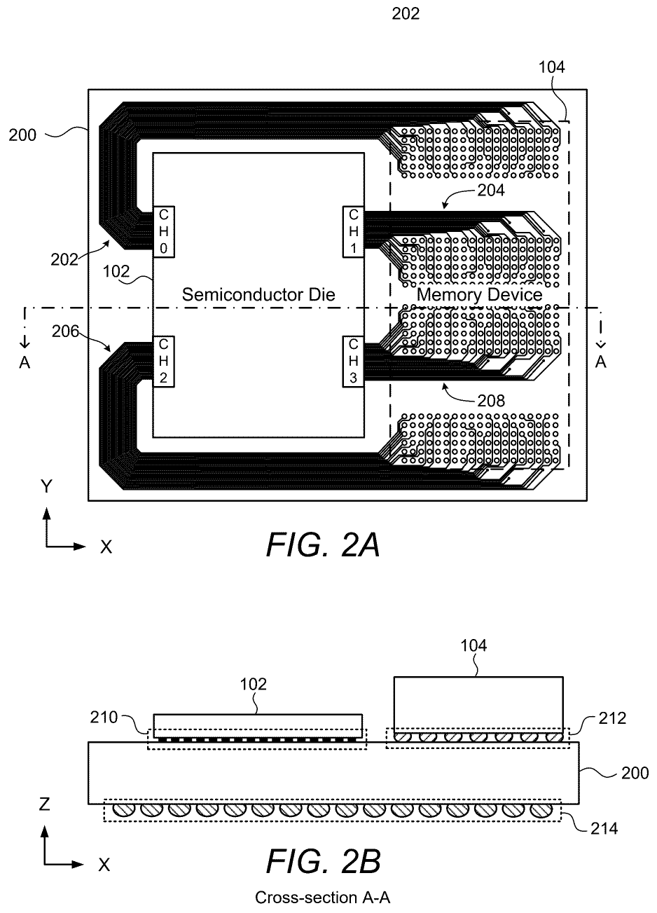

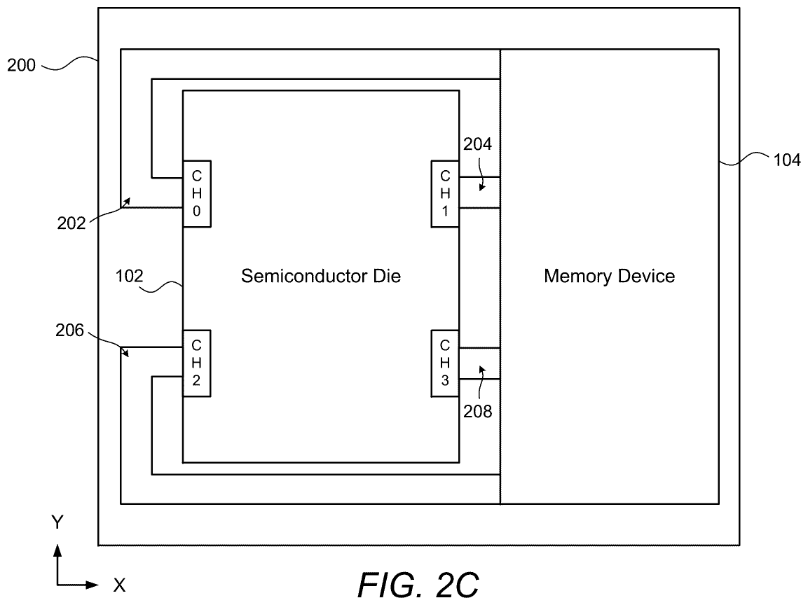

FIGS. 2A-C are various views of a conventional S×S POP device in which the memory devices 104 are grouped together on one side of the semiconductor die 102. In the example shown in FIGS. 2A-C, the position of the PHYs have not changed, i.e., the semiconductor die 102 in FIGS. 2A-C may be the same as the semiconductor die 102 in FIG. 1. The plan view in FIG. 2A shows four sets of electrical traces that connect the PHYs to the memory device 104, which include CH0 traces 202, CH1 traces 204, CH2 traces 206, and CH3 traces 208. The cross-sectional view in FIG. 2B shows the semiconductor device bonding pads 210, the memory device bonding pads 212 and the device under bump metal (UBM) structures 214. The simplified plan view in FIG. 2C illustrates the point that the CH0 traces 202, CH1 traces 204, CH2 traces 206, and CH3 traces 208 are traces on or within the substrate 200.

It can be seen that CH0 traces 202 and CH2 traces 206 are much longer than CH1 traces 204 and CH3 traces 208. For example, in one implementation, CH0 traces 202 and CH2 traces 206 are longer than 25 mm. These two longer channel traces not only increase routing space and package size, but also induce high risk of signal integrity degradation due to increased parasitic effects that result from the longer traces. A conventional approach to improve signal integrity is to increase the package size and the number of layers within the substrate 200, both of which increase size and cost of the device. Accordingly, a better approach is needed.

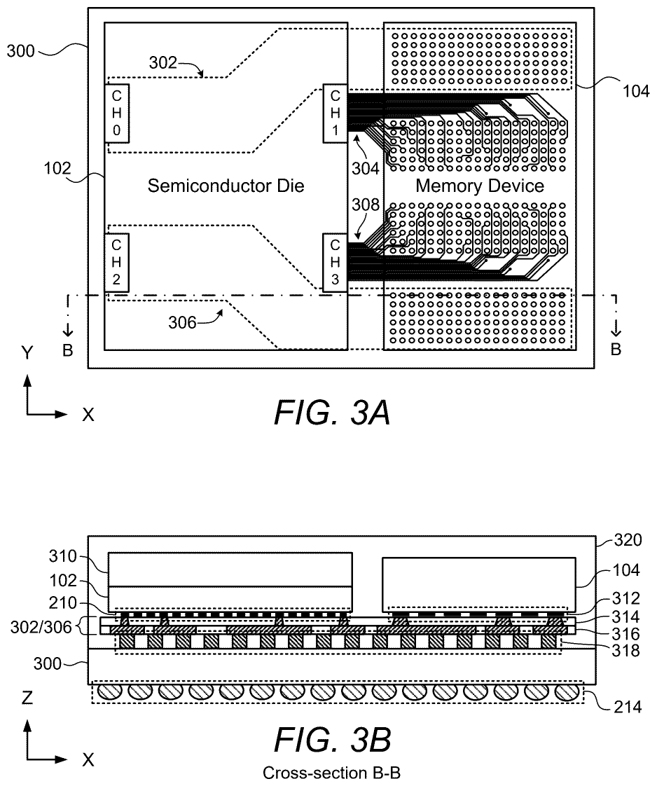

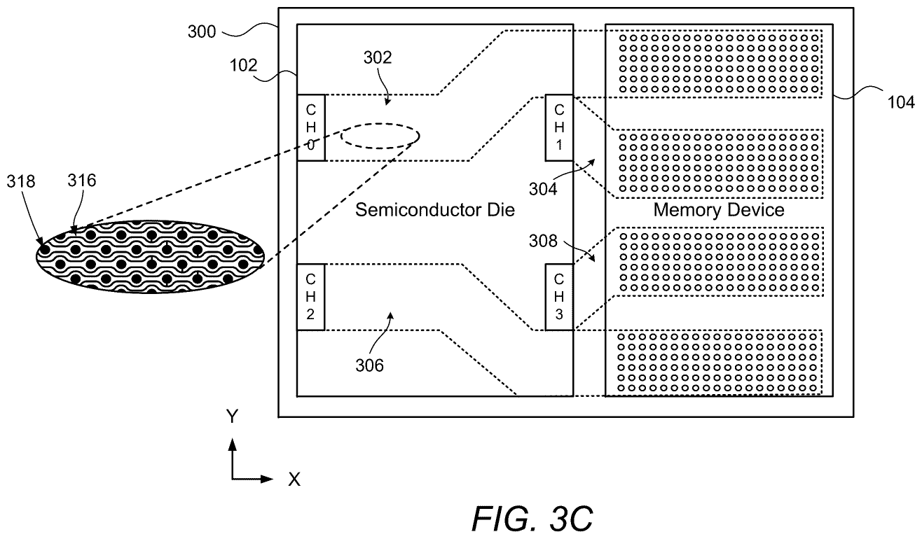

FIG. 3A and FIG. 3B are a plan view and a cross-sectional view, respectively, of a POP device according to aspects of the disclosure. FIGS. 3A-B show an S×S POP device in which the memory devices 104 are grouped together in one area of the substrate 300 with the semiconductor die 102 in another area of the substrate 300, according to aspects of the disclosure. In some aspects, the multiple memory devices previously located on opposite sides of the semiconductor die 102 as shown in FIG. 1 may be replaced with a lesser number of memory devices having the same functionality on just one side of the semiconductor die 102.

As shown in FIG. 3A, the position of the PHYs have not changed, i.e., the semiconductor die 102 in FIG. 3A may be the same as the semiconductor die 102 in FIG. 1. The plan view in FIG. 3A shows four sets of electrical traces that connect the PHYs to the memory device 104, which include CH0 traces 302, CH1 traces 304, CH2 traces 306, and CH3 traces 308, but unlike the conventional device shown in FIG. 2A, CH0 traces 302 and CH2 traces 306 are not substrate traces that run around the semiconductor die 102 but are instead traces within a routing structure that runs underneath the semiconductor die 102 and that has a finer line pitch than the substrate. For example, in one aspect, the substrate traces have a minimum line pitch of 10 microns and the routing structure traces have a line pitch of 5 microns. In another aspects, the substrate traces have a minimum line pitch of 6 microns and the routing structure traces have a line pitch of 2 microns.

In FIG. 3A, the individual CH0 traces 302 and CH2 traces 306 are not shown; instead, the possible locations of those traces are indicated as a dotted outline. It will be understood that the shapes of the possible locations of the CH0 traces 302 and CH2 traces 306 are illustrative and not limiting. In the example shown in FIG. 3A, the CH1 traces 304 and CH3 traces 308 are conventional traces that run on or within the substrate 300. It will be understood that the shapes and positions of the CH1 traces 304 and the CH3 traces 308 are illustrative and not limiting.

The cross-sectional view in FIG. 3B shows the semiconductor die 102, one of the memory devices 104, the semiconductor die bonding pads 210, and the UBM structures 214. These are essentially identical to their like numbered parts in FIGS. 1-2C and therefore their descriptions will not be repeated here. In the example shown in FIG. 3B, a dummy silicon structure 310 is mounted to the side of the semiconductor die 102 opposite the semiconductor die bonding pads 210. In some aspects, such as the example shown in FIG. 3B, the memory device contact pads 312 do not have solder balls on them. Instead, the semiconductor die bonding pads 210 and the memory device contact pads 312 are connected to the CH0 traces 302 and CH2 traces 306.

In some aspects, the CH0 traces 302 and the CH2 traces 306 comprise one or more metallization structures. The example shown in FIG. 3B includes one or more metallization layers 314 and a UBM layer 316. In some aspects, the one or more metallization layers 314 may comprise one or more redistribution layers (RDLs). Other numbers or combinations of high-density, fine-pitch metallization layers may be used instead.

The line pitch of the one or more metallization layers 314 is smaller than the line pitch of the substrate 300. For example, a typical RDL may have a minimum line width and line pitch of 15 micrometers (μm), while a typical pre-preg (PPG) substrate may have a minimum line width and line pitch of 100 μm or larger. As a result, an RDL can have up to six times more routing traces per given area (i.e., six times higher line density) than PPG substrates. These measurements and numbers are for illustration only and are not intended to limit the scope of the claims.

In the example shown in FIG. 3B, the one or more metallization layers include signal paths that flow around or connect with vertical conductors 318, which make electrical contact with electrical traces on the top surface of the substrate 300. In some aspects, an overmold layer 320 encapsulates the semiconductor die 102, memory device 104 and other components.

The structures shown herein according to aspects of the disclosure have a number of benefits over the conventional structures shown in FIGS. 1-2C. For example, because the CH0 traces 302 and the CH2 traces 306 are contained within the one or more metallization layers 314 and the UBM layer 316, the number of routing layers required for the substrate 300 may be reduced (e.g., from a 6-layer printed circuit board (PCB) to a 3-layer PCB), resulting in a thinner, cheaper substrate 300. Because CH0 traces 302 and the CH2 traces 306 can be located under the semiconductor die 102 (i.e., between the semiconductor die 102 and the substrate 300), those traces can be routed via a shorter, more direct path to the memory device 104, rather than going around the perimeter of the semiconductor die 102. This shorter path has less parasitic resistance, inductance, and capacitance than conventional longer paths, and thus has better signal integrity characteristics and smaller delay compared to conventional designs. In addition, the dimensions of the substrate 300 can be reduced since there is no longer a need to accommodate the substrate traces that went around the perimeter of the semiconductor die 102.

FIG. 3C is a simplified plan view of a POP device according to aspects of the disclosure, in which not only are the CH0 traces 302 and CH2 traces 306 routed via one or more RDL structures, but CH1 traces 304 and CH3 traces 308 are also routed via one or more RDL structures. In some aspects, these traces may be routed around and/or be connected to vertical conductors 318. Thus, in some aspects, fine RDL is used for DDR channels from the semiconductor die bonding pads 210 to the memory device contact pads 312. In addition, there will be vertical conductors 318 that connect the semiconductor die 102 substrate 300. In some aspects, the find RDL may be used to route input/output (I/O) signals or other signals along with the memory device channels. It will be understood that the dotted outlines that indicate possible locations of the various sets of traces are illustrative and not limiting.

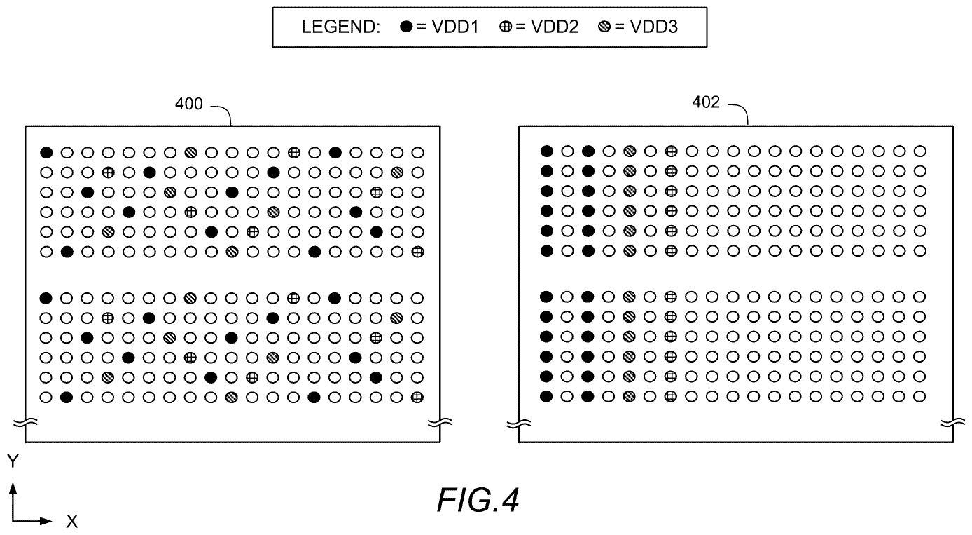

FIG. 4 illustrates an aspect in which the one or more metallization layers 314, the UBM layer 316, or other high-density, fine-pitched structures may be used as a pin layout converter (e.g., to convert from a standard pin layout for memory device contact pads 312, to another pin layout on the top surface of the substrate 300) according to aspects of the disclosure. In the example shown in FIG. 4, the power pins for a memory device 104 are typically distributed throughout the example power pin layout 400. If the memory device 104 having this power pin layout 400 were mounted directly to the substrate 300, the substrate would have to route power to those distributed power pins, which can complicate the design of traces on and within a substrate 300. In some aspects, the one or more metallization layers 314 and UBM layer 316 can be used to relocate the power pins such that the formerly distributed power pins in power pin layout 400 are grouped together for easier substrate-level routing, as shown in the power pin layout 402. In this example, therefore, the power pin layout 400 would match the layout required by the memory device contact pads 312 and would exist as such on the layer of the one or more metallization layers 314 closest to the memory device 312, and the power pin layout 402 would match the layout expected on the substrate 300 and would exist as such on the UBM layer 316.

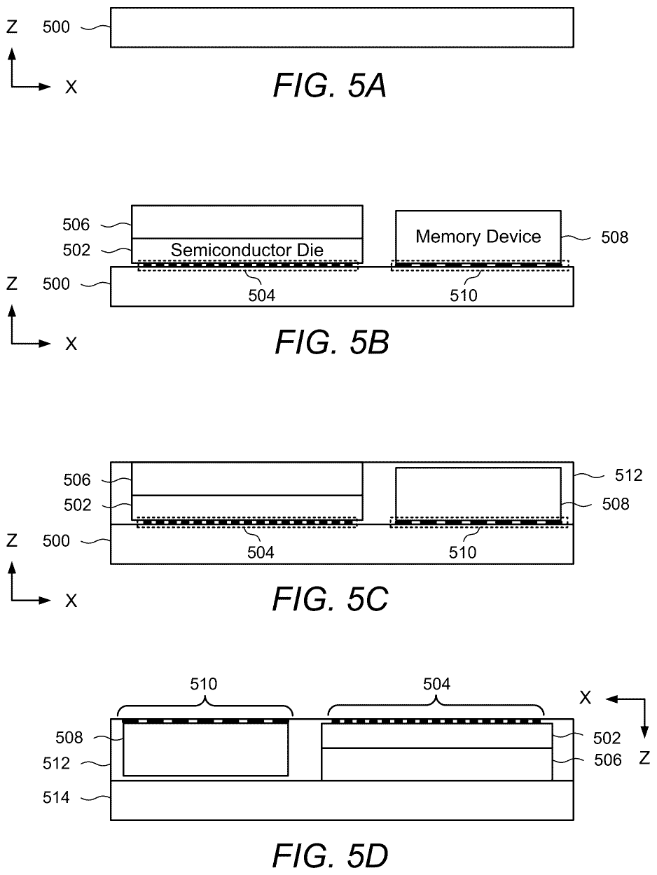

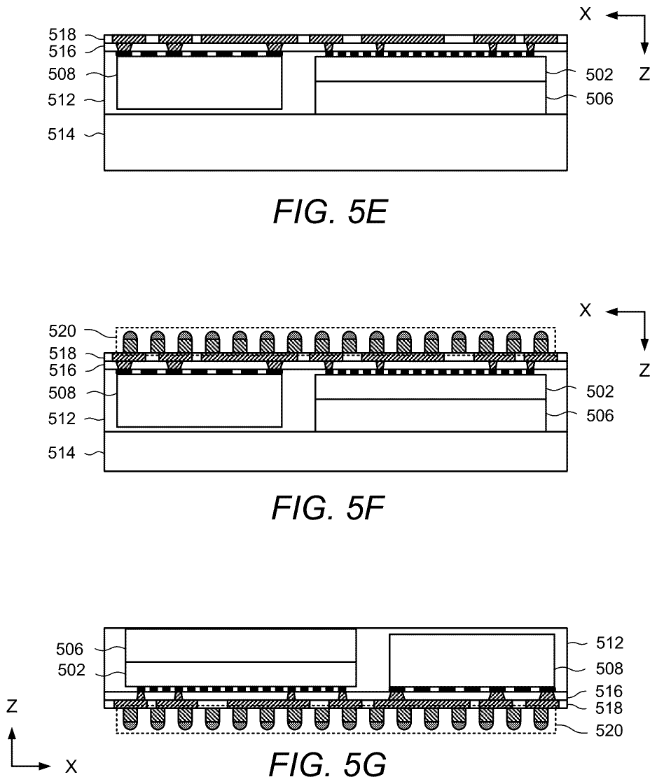

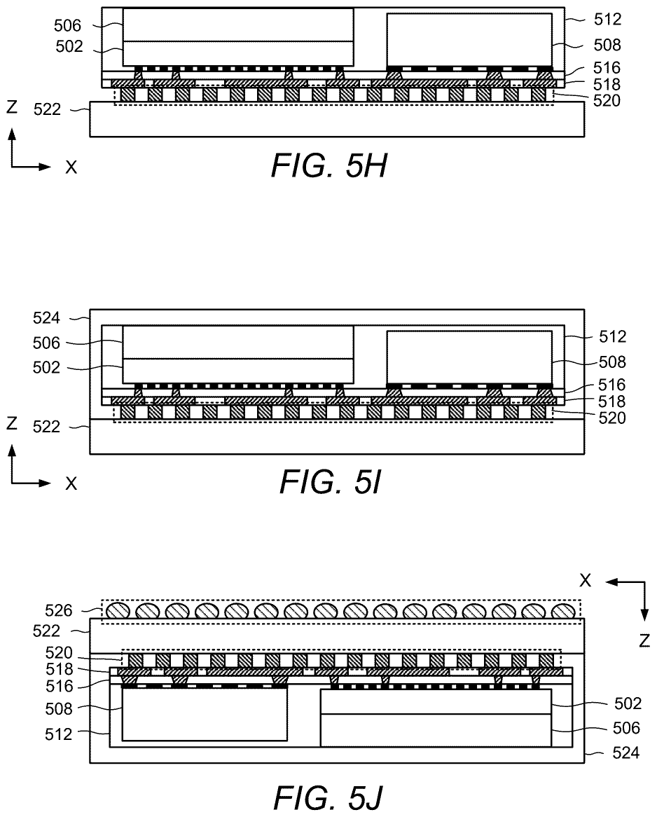

FIGS. 5A-J illustrate portions of a process for fabricating a high-density interconnect for semiconductor die and memory integration, according to aspects of the disclosure, according to aspects of the disclosure.

FIG. 5A illustrates a carrier 500 for RDL build-up, adhesive tape and then seed layer for copper (Cu) growth. Example materials for the carrier 500 include, but are not limited to, glass, ceramic, or a semiconductor wafer. For RDL build-up, the process may include placement of adhesive tape and a seed layer for Cu growth.

FIG. 5B shows the result after placement of a semiconductor die 502 with semiconductor die electrical contacts 504 (e.g., Cu pads on UBM) facing the carrier 500 and an optional dummy layer 506 attached to the semiconductor die 502 on the side opposite the semiconductor die electrical contacts 504, and the placement of a memory 508 with memory electrical contacts 510 (without solder balls) facing the carrier 500. For both the semiconductor die 502 and the memory 508, the active side is facing down towards the carrier 500. The optional dummy layer 506 may not be needed if the semiconductor die 502 and the memory 508 have similar thicknesses. When used, the optional dummy layer 506 provides a thermal conducting path away from the semiconductor die 502.

FIG. 5C shows the result after an overmold process that encapsulates the semiconductor die 502, dummy layer 506, and memory 508 in a first overmold material 512 that is then ground (e.g., by back-grinding) to a desired thickness.

FIG. 5D shows the result of detaching the carrier 500 and placement of a carrier 514 (which may be carrier 500 reused or a new carrier) on the opposite side in preparation for an RDL build-up that makes contact with the semiconductor die electrical contacts 504 and the memory electrical contacts 510.

FIG. 5E shows the result after fabrication of one or more metallization layers 516 and a layer of UBM structures 518. In some aspects, the one or more metallization layers 516 may comprise one or more RDL layers, with two RDL layers typically being sufficient. In some aspects, RDL layers include dielectric layers that are 4 microns thick interspersed with metal layers that are also 4 microns thick.

In some aspects, the one or more metallization layers 516 may be fabricated by using a process that includes a photomask (PM) coat step, a PM expose step, a develop step, a seed deposit step, and an RDL process that includes lithography, plating, stripping, and etching steps. Example dielectric materials between the metal traces include, but are not limited to, polyimide. It is noted that the process to fabricate the one or more metallization layers 516 does not require application of solder materials to the contacts of the semiconductor die electrical contacts 504 or the memory electrical contacts 510.

In some aspects, the UBM structures 518 may be fabricated by using a process that includes a PM coat step, a PM expose step, a develop step, a seed deposit step, and a UBM process that includes lithography, plating, stripping, and etching steps.

FIG. 5F shows the result after creation of Cu pillars 520 for feedthrough bumps that will connect the pins of the semiconductor die 502 and/or the memory 508 to the package substrate to be added later in the process. Some UBM structures 518 may not require a Cu pillar 520. In some aspects, solder is deposited on the tops of the Cu pillars 520 in preparation for attaching a package parent laminate substrate to the tops of the Cu pillars 520.

FIG. 5G shows the result after removal of the carrier 514. The one or more metallization layers 516 provides the compact memory interconnect channels under the semiconductor die 502 die and create feedthrough for the Cu pillars 520.

FIG. 5H shows the result after the attachment of the structure in FIG. 5G to a package substrate 522. In some aspects, the Cu pillars 520 are connected to the substrate 522 using thermal compression bonding, mass reflow, or other attachment techniques. In some aspects, the package substrate 522 is comprised of a set of laminate layers, which may Ajinomoto build-up film (ABF) and/or PPG, and may be fabricated by a PCB or substrate process. Example dielectric materials include, but are not limited to, woven glass fiber.

Because of the interconnections between the semiconductor die 502 and the memory 508 provided by the one or more metallization layers 516, the number of layers needed by the package substrate 522 can be reduced, e.g., from six layers to three layers, for example. For a package substrate 522 having dielectric layers that are 20 microns thick and copper signal layers that are 15 microns thick, going from six to three layers translates to a reduction in thickness by 100 microns or more, while a two-RDL-layer metallization structure 516 may add only an additional 6-8 microns of thickness.

FIG. 5I shows the result after a second overmold process that encapsulates the semiconductor die 502, dummy layer 506, and memory 508, the first overmold material 512, the one or more metallization layers 516, the UBM structures 518, and the Cu pillars 520 in a second overmold material 524.

FIG. 5J shows the result after creation of ball grid array (BGA) contacts 526 on the side of the package substrate 522 opposite the semiconductor die 502 and memory 508. The process may include singulation, e.g., if the package substrate 522 is a strip format substrate, etc.

It will be appreciated that the foregoing fabrication process was provided merely as a general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

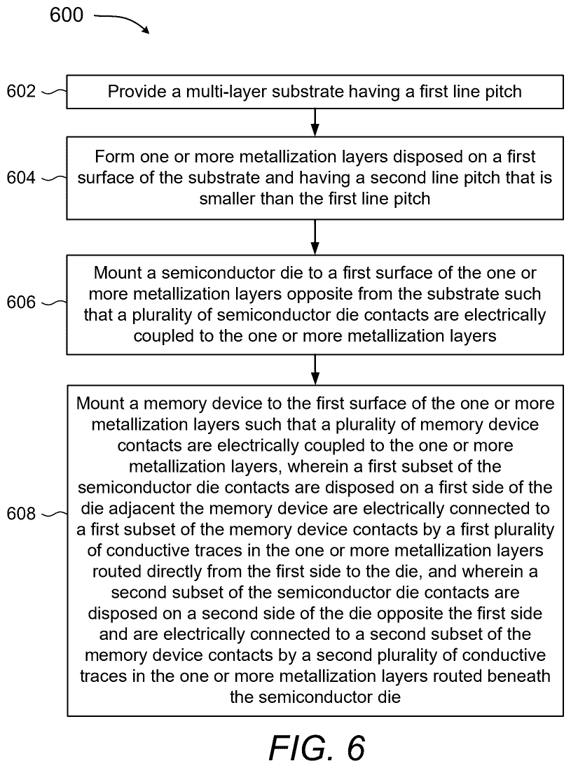

FIG. 6 is a flowchart of an example method 600 for fabricating a semiconductor apparatus having a high-density interconnect for semiconductor die and memory integration, according to aspects of the disclosure.

As shown in FIG. 6, method 600 may include, at block 602, providing a multi-layer substrate having a first line pitch. In some aspects, providing the substrate comprises providing copper-clad laminate (CCL), PPG, a PCB, or a combination thereof. In some aspects, providing the substrate comprises providing a substrate having two or more layers. In some aspects, providing the substrate comprises providing a substrate having a thickness in a range from 100 microns to 150 microns.

As further shown in FIG. 6, method 600 may include, at block 604, forming one or more metallization layers on a top surface the substrate and having a second line pitch that is smaller than the first line pitch. In some aspects, forming the one or more metallization layers comprises forming a redistribution layer (RDL). In some aspects, forming the RDL comprises forming an RDL having one routing layer. In some aspects, forming the RDL comprises forming an RDL having two or more routing layers. In some aspects, a ratio of the number of routing layers in the substrate to the number of routing layers in the one or more metallization layers is N:M, where N is greater than or equal to M (e.g., having a ratio of 1:1, 2:1, 3:1, 3:2, 4:1, or 4:3). In some aspects, forming the one or more metallization layers comprises forming a plurality of vertical conductors to which the plurality of semiconductor die contacts are mounted. In some aspects, forming the plurality of vertical conductors comprises forming copper (Cu) pillars. In some aspects, forming the one or more metallization layers comprises forming at least some electrical traces within the one or more metallization layers and underneath the semiconductor die that are routed between the vertical conductors. In some aspects, forming the one or more metallization layers further comprises forming electrical traces that provide electrical connections other than connections between the semiconductor die and memory device.

As further shown in FIG. 6, method 600 may include, at block 606, mounting a semiconductor die to the top surface of the one or more metallization layers such that a plurality of semiconductor die contacts are electrically coupled to the one or more metallization layers. In some aspects, mounting a semiconductor die comprises mounting a processor or a system-on-chip (SOC) device.

As further shown in FIG. 6, method 600 may include, at block 608, mounting a memory device to the top surface of the one or more metallization layers such that a plurality of memory device contacts are electrically coupled to the one or more metallization layers. In some aspects, mounting the memory device comprises mounting a dynamic random access memory (DRAM) device. In some aspects, each of the first subset of the semiconductor die contacts and the second subset of the semiconductor die contacts comprises a physical (PHY) layer interface between the semiconductor die and the memory device.

In some aspects, a first subset of the semiconductor die contacts are disposed on a first side of the die adjacent the memory device are electrically connected to a first subset of the memory device contacts by a first plurality of conductive traces in the one or more metallization layers routed directly from the first side to the die, and wherein a second subset of the semiconductor die contacts are disposed on a second side of the die opposite the first side and are electrically connected to a second subset of the memory device contacts by a second plurality of conductive traces in the one or more metallization layers routed beneath the semiconductor die. In some aspects, at least some of the first plurality of conductive traces include a segment comprising an electrical trace in the multi-layer substrate. In some aspects, at least one conductive trace in the first plurality of conductive traces or the second plurality of conductive traces includes a segment comprising an electrical trace in the multi-layer substrate.

In some aspects, the semiconductor die and the memory device are mounted side by side on the top surface of the substrate and wherein the first subset of semiconductor die contacts is closer to the memory device than the second subset of semiconductor die contacts. In some aspects, the first subset of semiconductor die contacts are on a first side of the semiconductor die that is closest to the memory device and the second subset of semiconductor die contacts are on a second side of the semiconductor die that is farthest from the memory device.

In some aspects, method 600 includes incorporating the apparatus into another apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Method 600 may include additional implementations, such as any single implementation or any combination of implementations described below and/or in connection with one or more other methods described elsewhere herein. Although FIG. 6 shows example blocks of method 600, in some implementations, method 600 may include additional blocks, fewer blocks, different blocks, or differently arranged blocks than those depicted in FIG. 6. Additionally, or alternatively, two or more of the blocks of method 600 may be performed in parallel.

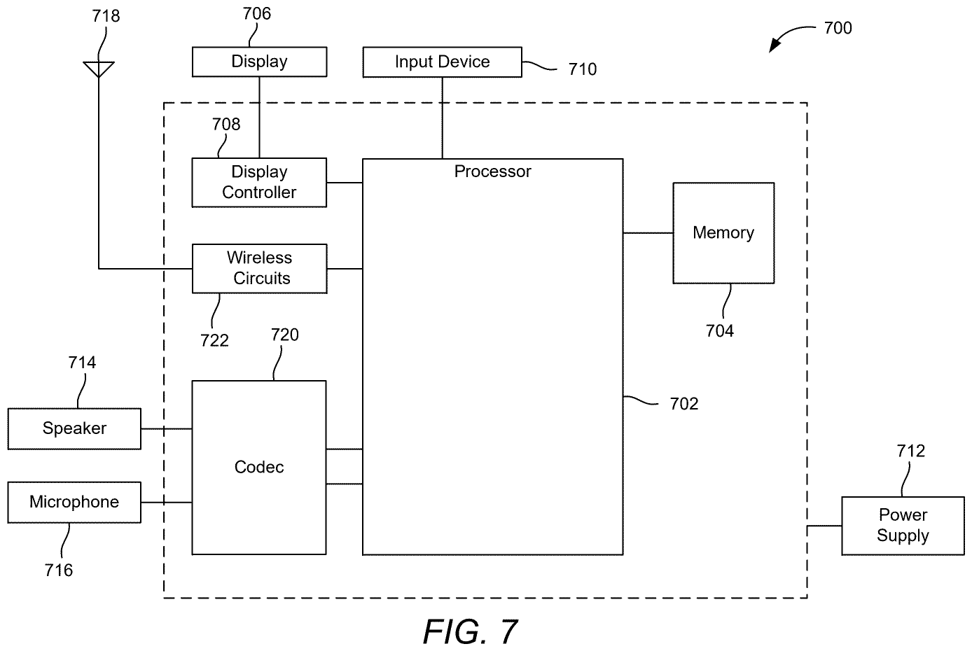

FIG. 7 illustrates a mobile device 700, according to aspects of the disclosure. In some aspects, the mobile device 700 may be implemented by including one or more integrated circuit (IC) devices manufactured based on the examples described in this disclosure.

In some aspects, mobile device 700 may be configured as a wireless communication device. As shown, mobile device 700 includes processor 702. Processor 702 may be communicatively coupled to memory 704 over a link, which may be a die-to-die or chip-to-chip link. Mobile device 700 also includes display 706 and display controller 708, with display controller 708 coupled to processor 702 and to display 706. The mobile device 700 may include input device 710 (e.g., physical, or virtual keyboard), power supply 712 (e.g., battery), speaker 714, microphone 716, and wireless antenna 718. In some aspects, the power supply 712 may directly or indirectly provide the supply voltage for operating some or all of the components of the mobile device 700.

In some aspects, FIG. 7 may include coder/decoder (CODEC) 720 (e.g., an audio and/or voice CODEC) coupled to processor 702; speaker 714 and microphone 716 coupled to CODEC 720; and wireless circuits 722 (which may include a modem, radio frequency (RF) circuitry, filters, etc.) coupled to wireless antenna 718 and to processor 702.

In some aspects, one or more of processor 702, display controller 708, memory 704, CODEC 720, and wireless circuits 722 may include one or more IC devices including semiconductor structures manufactured according to the examples described in this disclosure.

It should be noted that although FIG. 7 depicts a mobile device 700, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

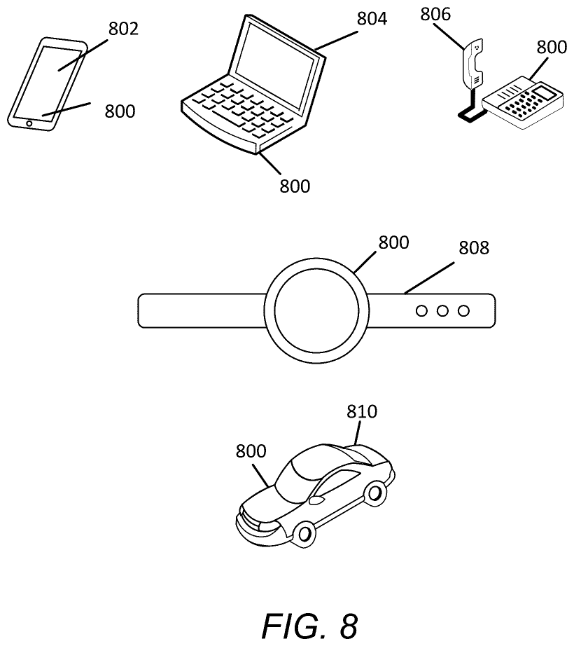

FIG. 8 illustrates various electronic devices that may be integrated with any of the aforementioned devices, semiconductor devices, IC packages, IC devices, semiconductor devices, integrated circuits, electronic components, interposer packages, package-on-package (PoP), System in Package (SiP), or System on Chip (SoC). For example, a mobile phone device 802, a laptop computer device 804, a fixed location terminal device 806, a wearable device 808, or automotive vehicle 810 may include a semiconductor device 800 (e.g., the semiconductor device illustrated in FIG. 3) as described herein. The devices 802, 804, 806 and 808 and the vehicle 810 illustrated in FIG. 8 are merely exemplary. Other apparatuses or devices may also feature the semiconductor device 800 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. An apparatus, comprising: a multi-layer substrate having a first line pitch; one or more metallization layers disposed on a first surface of the substrate and having a second line pitch that is smaller than the first line pitch; a semiconductor die mounted to a first surface of the one or more metallization layers opposite from the substrate such that a plurality of semiconductor die contacts are electrically coupled to the one or more metallization layers; and a memory device mounted to the first surface of the one or more metallization layers such that a plurality of memory device contacts are electrically coupled to the one or more metallization layers, wherein a first subset of the semiconductor die contacts are disposed on a first side of the die adjacent the memory device are electrically connected to a first subset of the memory device contacts by a first plurality of conductive traces in the one or more metallization layers routed directly from the first side to the die, and wherein a second subset of the semiconductor die contacts are disposed on a second side of the die opposite the first side and are electrically connected to a second subset of the memory device contacts by a second plurality of conductive traces in the one or more metallization layers routed beneath the semiconductor die.

Clause 2. The apparatus of clause 1, wherein at least some of the first plurality of conductive traces include a segment comprising an electrical trace in the multi-layer substrate.

Clause 3. The apparatus of any of clauses 1 to 2, wherein the semiconductor die and the memory device are mounted side by side on the first surface of the substrate.

Clause 4. The apparatus of any of clauses 1 to 3, wherein the substrate comprises copper-clad laminate (CCL), pre-preg (PPG), a printed circuit board (PCB), or a combination thereof.

Clause 5. The apparatus of any of clauses 1 to 4, wherein the substrate comprises two or more layers.

Clause 6. The apparatus of any of clauses 1 to 5, wherein the substrate has a thickness in a range from 100 microns to 150 microns.

Clause 7. The apparatus of any of clauses 1 to 6, wherein the one or more metallization layers comprises a redistribution layer (RDL).

Clause 8. The apparatus of clause 7, wherein the RDL comprises one routing layer.

Clause 9. The apparatus of any of clauses 7 to 8, wherein the RDL comprises two or more routing layers.

Clause 10. The apparatus of any of clauses 1 to 9, wherein a ratio of a number of routing layers in the substrate to a number of routing layers in the one or more metallization layers is N:M, where N is greater than or equal to M.

Clause 11. The apparatus of any of clauses 1 to 10, wherein the one or more metallization layers comprises a plurality of vertical conductors to which the plurality of semiconductor die contacts are mounted.

Clause 12. The apparatus of clause 11, wherein the plurality of vertical conductors comprise copper (Cu) pillars.

Clause 13. The apparatus of any of clauses 11 to 12, wherein at least some electrical traces within the one or more metallization layers and underneath the semiconductor die are routed between the vertical conductors.

Clause 14. The apparatus of any of clauses 1 to 13, wherein the one or more metallization layers further comprises electrical traces that provide electrical connections other than connections between the semiconductor die and memory device.

Clause 15. The apparatus of any of clauses 1 to 14, wherein each of the first subset of the semiconductor die contacts and the second subset of the semiconductor die contacts comprises a physical (PHY) layer interface between the semiconductor die and the memory device.

Clause 16. The apparatus of any of clauses 1 to 15, wherein the memory device comprises a dynamic random access memory (DRAM) device.

Clause 17. The apparatus of any of clauses 1 to 16, wherein the apparatus is incorporated into another apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Clause 18. A method for fabricating an apparatus, the method comprising: providing a multi-layer substrate having a first line pitch; forming one or more metallization layers on a first surface of the substrate and having a second line pitch that is smaller than the first line pitch; mounting a semiconductor die to a first surface of the one or more metallization layers opposite from the substrate such that a plurality of semiconductor die contacts are electrically coupled to the one or more metallization layers; and mounting a memory device to the first surface of the one or more metallization layers such that a plurality of memory device contacts are electrically coupled to the one or more metallization layers, wherein a first subset of the semiconductor die contacts are disposed on a first side of the die adjacent the memory device are electrically connected to a first subset of the memory device contacts by a first plurality of conductive traces in the one or more metallization layers routed directly from the first side to the die, and wherein a second subset of the semiconductor die contacts are disposed on a second side of the die opposite the first side and are electrically connected to a second subset of the memory device contacts by a second plurality of conductive traces in the one or more metallization layers routed beneath the semiconductor die.

Clause 19. The method of clause 18, wherein at least some of the first plurality of conductive traces include a segment comprising an electrical trace in the multi-layer substrate.

Clause 20. The method of any of clauses 18 to 19, wherein the semiconductor die and the memory device are mounted side by side on the first surface of the substrate.

Clause 21. The method of any of clauses 18 to 20, wherein providing the substrate comprises providing copper-clad laminate (CCL), pre-preg (PPG), a printed circuit board (PCB), or a combination thereof.

Clause 22. The method of any of clauses 18 to 21, wherein providing the substrate comprises providing a substrate having two or more layers.

Clause 23. The method of any of clauses 18 to 22, wherein providing the substrate comprises providing a substrate having a thickness in a range from 100 microns to 150 microns.

Clause 24. The method of any of clauses 18 to 23, wherein forming the one or more metallization layers comprises forming a redistribution layer (RDL).

Clause 25. The method of clause 24, wherein forming the RDL comprises forming an RDL having one routing layer.

Clause 26. The method of any of clauses 24 to 25, wherein forming the RDL comprises forming an RDL having two or more routing layers.

Clause 27. The method of any of clauses 18 to 26, wherein a ratio of a number of routing layers in the substrate to a number of routing layers in the one or more metallization layers is N: M, where N is greater than or equal to M.

Clause 28. The method of any of clauses 18 to 27, wherein forming the one or more metallization layers comprises forming a plurality of vertical conductors to which the plurality of semiconductor die contacts are mounted.

Clause 29. The method of clause 28, wherein forming the plurality of vertical conductors comprises forming copper (Cu) pillars.

Clause 30. The method of any of clauses 28 to 29, wherein forming the one or more metallization layers comprises forming at least some electrical traces within the one or more metallization layers and underneath the semiconductor die that are routed between the vertical conductors.

Clause 31. The method of any of clauses 18 to 30, wherein forming the one or more metallization layers further comprises forming electrical traces that provide electrical connections other than connections between the semiconductor die and memory device.

Clause 32. The method of any of clauses 18 to 31, wherein each of the first subset of the semiconductor die contacts and the second subset of the semiconductor die contacts comprises a physical (PHY) layer interface between the semiconductor die and the memory device.

Clause 33. The method of any of clauses 18 to 32, wherein mounting the memory device comprises mounting a dynamic random access memory (DRAM) device.

Clause 34. The method of any of clauses 18 to 33, further comprising incorporating the apparatus into another apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a digital signal processor (DSP), an application-specific integrated circuit (ASIC), a field programmable gate array (FPGA), or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order. Further, no component, function, action, or instruction described or claimed herein should be construed as critical or essential unless explicitly described as such. Furthermore, as used herein, the terms “set,” “group,” and the like are intended to include one or more of the stated elements. Also, as used herein, the terms “has,” “have,” “having,” “comprises,” “comprising,” “includes,” “including,” and the like does not preclude the presence of one or more additional elements (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more of the stated elements. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination.

What is claimed is:

1. An apparatus, comprising:
a multi-layer substrate having a first line pitch;
one or more metallization layers disposed on a first surface of the substrate and having a second line pitch that is smaller than the first line pitch;
a semiconductor die mounted to a first surface of the one or more metallization layers opposite from the substrate such that a plurality of semiconductor die contacts are electrically coupled to the one or more metallization layers; and
a memory device mounted to the first surface of the one or more metallization layers such that a plurality of memory device contacts are electrically coupled to the one or more metallization layers,
wherein a first subset of the semiconductor die contacts are disposed on a first side of the die adjacent the memory device are electrically connected to a first subset of the memory device contacts by a first plurality of conductive traces in the one or more metallization layers routed directly from the first side to the die, and
wherein a second subset of the semiconductor die contacts are disposed on a second side of the die opposite the first side and are electrically connected to a second subset of the memory device contacts by a second plurality of conductive traces in the one or more metallization layers routed beneath the semiconductor die.

2. The apparatus of claim 1, wherein at least some of the first plurality of conductive traces include a segment comprising an electrical trace in the multi-layer substrate.

3. The apparatus of claim 1, wherein the semiconductor die and the memory device are mounted side by side on the first surface of the substrate.

4. The apparatus of claim 1, wherein the substrate comprises copper-clad laminate (CCL), pre-preg (PPG), a printed circuit board (PCB), or a combination thereof.

5. The apparatus of claim 1, wherein the substrate comprises two or more layers.

6. The apparatus of claim 1, wherein the substrate has a thickness in a range from 100 microns to 150 microns.

7. The apparatus of claim 1, wherein the one or more metallization layers comprises a redistribution layer (RDL).

8. The apparatus of claim 7, wherein the RDL comprises one routing layer.

9. The apparatus of claim 7, wherein the RDL comprises two or more routing layers.

10. The apparatus of claim 1, wherein a ratio of a number of routing layers in the substrate to a number of routing layers in the one or more metallization layers is N:M, where N is greater than or equal to M.

11. The apparatus of claim 1, wherein the one or more metallization layers comprises a plurality of vertical conductors to which the plurality of semiconductor die contacts are mounted.

12. The apparatus of claim 11, wherein the plurality of vertical conductors comprise copper (Cu) pillars.

13. The apparatus of claim 11, wherein at least some electrical traces within the one or more metallization layers and underneath the semiconductor die are routed between the vertical conductors.

14. The apparatus of claim 1, wherein the one or more metallization layers further comprises electrical traces that provide electrical connections other than connections between the semiconductor die and memory device.

15. The apparatus of claim 1, wherein each of the first subset of the semiconductor die contacts and the second subset of the semiconductor die contacts comprises a physical (PHY) layer interface between the semiconductor die and the memory device.

16. The apparatus of claim 1, wherein the memory device comprises a dynamic random access memory (DRAM) device.

17. The apparatus of claim 1, wherein the apparatus is incorporated into another apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

18. A method for fabricating an apparatus, the method comprising:
providing a multi-layer substrate having a first line pitch;
forming one or more metallization layers on a first surface of the substrate and having a second line pitch that is smaller than the first line pitch;
mounting a semiconductor die to a first surface of the one or more metallization layers opposite from the substrate such that a plurality of semiconductor die contacts are electrically coupled to the one or more metallization layers; and
mounting a memory device to the first surface of the one or more metallization layers such that a plurality of memory device contacts are electrically coupled to the one or more metallization layers,
wherein a first subset of the semiconductor die contacts are disposed on a first side of the die adjacent the memory device are electrically connected to a first subset of the memory device contacts by a first plurality of conductive traces in the one or more metallization layers routed directly from the first side to the die, and
wherein a second subset of the semiconductor die contacts are disposed on a second side of the die opposite the first side and are electrically connected to a second subset of the memory device contacts by a second plurality of conductive traces in the one or more metallization layers routed beneath the semiconductor die.

19. The method of claim 18, wherein providing the substrate comprises providing copper-clad laminate (CCL), pre-preg (PPG), a printed circuit board (PCB), or a combination thereof and wherein forming the one or more metallization layers comprises forming a redistribution layer (RDL).

20. The method of claim 18, wherein each of the first subset of the semiconductor die contacts and the second subset of the semiconductor die contacts comprises a physical (PHY) layer interface between the semiconductor die and the memory device.
